(19) United States
(12) Patent Application Publication
(10) Pub. No.: US 2014/0374866 A1
(43) Pub. Date: Dec. 25, 2014

(54) Photo Sensing Chip Having a Plurality of Photo Sensors and Manufacturing Method Thereof

(71) Applicant: uPI semiconductor corp., Zhubei City (TW)

(72) Inventor: Ping-Yuan Lin, Zhubei City (TW)

(73) Assignee: uPI semiconductor corp., Zhubei City (TW)

(21) Appl. No.: 14/295,451

(22) Filed: Jun. 4, 2014

(30) Foreign Application Priority Data
Jun. 20, 2013 (TW) 102121910

(51) Int. Cl. H01L 27/144; H01L 31/18

(52) U.S. Cl. CPC H01L 27/1443; H01L 31/18
USPC 257/443; 438/73

(57) ABSTRACT

A photo sensing chip and a manufacturing method thereof are disclosed. The photo sensing chip includes a silicon substrate and a plurality of photo sensors formed on the silicon substrate. The photo sensors include a first photo sensor and a second photo sensor. The first photo sensor has a first P-N junction and a first depletion region is formed at first P-N junction for receiving a first light band of an incident light to generate a first photo current. The second photo sensor has a second P-N junction and a second depletion region is formed at second P-N junction for receiving a second light band of the incident light to generate a second photo current. A first process parameter corresponds to the first depletion region and a second process parameter corresponds to the second depletion region, wherein the first process parameter and the second process parameter are different.

### BACKGROUND OF THE INVENTION

1. Field of the Invention

The invention relates to a photo sensor; in particular, to a photo sensing chip having a plurality of photo sensors and a manufacturing method thereof.

2. Description of the Prior Art

In general, in order to make photo sensors only respond to the lights of a specific wavelength range, not only a P-N junction diode is made by standard silicon process, but also a photo resist layer of specific material is coated on the P-N junction diode as a color filter to filter the light signals out of the specific wavelength range.

Because the above-mentioned standard silicon process and after-process treatment of the conventional photo sensor are done in different plants respectively, the manufacturing and transportation costs of the conventional photo sensors are increased. For example, after a chip having photo sensors is made in a fab, the chip having photo sensors must be sent to the after-process plant to be coated a photo resist layer, and then the chip having photo sensors is sent to an IC packaging and testing plant to be packaged and tested. In addition, in many applications, it is necessary to dispose photo sensors sensing different wavelength ranges on the same photo sensing chip simultaneously. However, when the photo sensors sensing different wavelength ranges are disposed on the same photo sensing chip, additional color filter layers should be coated on the same photo sensing chip. This will make the overall process become more complicated and make the manufacturing efficiency become poorer.

Please refer to FIG. 1. FIG. 1 illustrates a schematic diagram of a red-light sensor, a green-light sensor, and a blue-light sensor formed on a conventional photo sensing chip. As shown in FIG. 1, because a first color filter RF, a second color filter GF, and a third color filter BF are formed on the red-light sensor RS, the green-light sensor GS, and the blue-light sensor BS respectively, the process of manufacturing the conventional photo sensing chip will become more complicated.

### SUMMARY OF THE INVENTION

Therefore, the invention provides a photo sensing chip having a plurality of photo sensors and a manufacturing method thereof capable of sensing lights of different bands without color filters to solve the above-mentioned problems occurred in the prior arts.

A scope of the invention is to provide a photo sensing chip. In a preferred embodiment, the photo sensing chip includes a silicon substrate and a plurality of photo sensors. The photo sensors are formed on the silicon substrate. The photo sensors include a first photo sensor and a second photo sensor. The first photo sensor has a first P-N junction and a first depletion region is formed at first P-N junction for receiving a first light band of an incident light to generate a first photo current. The second photo sensor has a second P-N junction and a second depletion region is formed at second P-N junction for receiving a second light band of the incident light to generate a second photo current. A first process parameter corresponds to the first depletion region and a second process parameter corresponds to the second depletion region. The first process parameter and the second process parameter are different.

In an embodiment, the first process parameter and the second process parameter are related to a doping material. A first doping material of the first depletion region and a second doping material of the second depletion region are different.

In an embodiment, the first process parameter and the second process parameter are related to depths of the first depletion region and the second depletion region. A first depth of the first depletion region and a second depth of the second depletion region are different.

In an embodiment, the first photo sensor and the second photo sensor are formed on the silicon substrate side by side or stacked on the silicon substrate.

In an embodiment, the photo sensing chip further includes an operation circuit. The operation circuit is coupled to the photo sensors and used for obtaining an incident spectrum according to at least one of the first photo current and the second photo current.

In an embodiment, the photo sensors are selected from a group formed by a red-light sensor, a green-light sensor, a blue-light sensor, an ambient light sensor, a proximity sensor, and a UV sensor.

Another scope of the invention is to provide a photo sensing chip manufacturing method. In a preferred embodiment, the photo sensing chip manufacturing method includes steps of: (a) providing a silicon substrate; and (b) forming a plurality of photo sensors on the silicon substrate. The step (b) includes steps of: (b1) forming a first photo sensor having a first P-N junction, and forming a first depletion region at the first P-N junction to receive a first light band of an incident light and generate a first photo current; and (b2) forming a second photo sensor having a second P-N junction, and forming a second depletion region at the second P-N junction to receive a second light band of the incident light and generate a second photo current. A first process parameter corresponds to the first depletion region and a second process parameter corresponds to the second depletion region. The first process parameter and the second process parameter are different.

Compared with the prior arts, since it is unnecessary to dispose any color filter in the photo sensing chip having photo sensors of the invention, the photo sensing chip of the invention can be made in the same plant to effectively lower the manufacturing and transportation costs and reduce the process complexity. In addition, the photo sensors can be stacked on the photo sensing chip in the invention to reduce the photo sensing area of the photo sensing chip to achieve effects of reducing area, lowering cost, and enhancing chip efficiency.

The advantage and spirit of the invention may be understood by the following detailed descriptions together with the appended drawings.

### BRIEF DESCRIPTION OF THE APPENDED DRAWINGS

FIG. 1 illustrates a schematic diagram of a red-light sensor, a green-light sensor, and a blue-light sensor formed on a conventional photo sensing chip.

FIG. 2 illustrates a schematic diagram of a structure of the photo sensing chip in the invention.

FIG. 3A, FIG. 3B, and FIG. 3C illustrate the cross-sectional diagrams of the first photo sensor, the second photo sensor, and the third photo sensor of FIG. 2 respectively.

FIG. 4A illustrates the equivalent circuit diagram of the first photo sensor, the second photo sensor, and the third photo sensor of FIG. 2.

FIG. 4B illustrates that the operation circuit operates the first photo current, the second photo current, and/or the third photo current generated by the first photo sensor, the second photo sensor, and the third photo sensor.

FIG. 5 illustrates a schematic diagram of another structure of the photo sensing chip in the invention.

FIG. 6 illustrates the cross-sectional diagram of the photo sensing chip of FIG. 5.

FIG. 7A illustrates the equivalent circuit diagram of the first photo sensor, the second photo sensor, the third photo sensor, the fourth photo sensor, the fifth photo sensor, the sixth photo sensor, and the seventh photo sensor of FIG. 5.

FIG. 7B illustrates that the operation circuit operates the first photo current, the second photo current, the third photo current, the fourth photo current, the fifth photo current, the sixth photo current, and/or the seventh photo current generated by the first photo sensor, the second photo sensor, the third photo sensor, the fourth photo sensor, the fifth photo sensor, the sixth photo sensor, and the seventh photo sensor.

FIG. 8 illustrates a flow chart of the photo sensing chip manufacturing method in an embodiment of the invention.

FIG. 9 illustrates a flow chart of the photo sensing chip manufacturing method in another embodiment of the invention.

### DETAILED DESCRIPTION OF THE INVENTION

A preferred embodiment of the invention is a photo sensing chip having photo sensors. In practical applications, the photo sensors of the photo sensing chip can include a red-light sensor, a green-light sensor, a blue-light sensor, an ambient light sensor, a proximity sensor, a UV sensor, or any other types of sensor. The number of the photo sensors can be adjusted based on practical needs; it is not limited to this case.

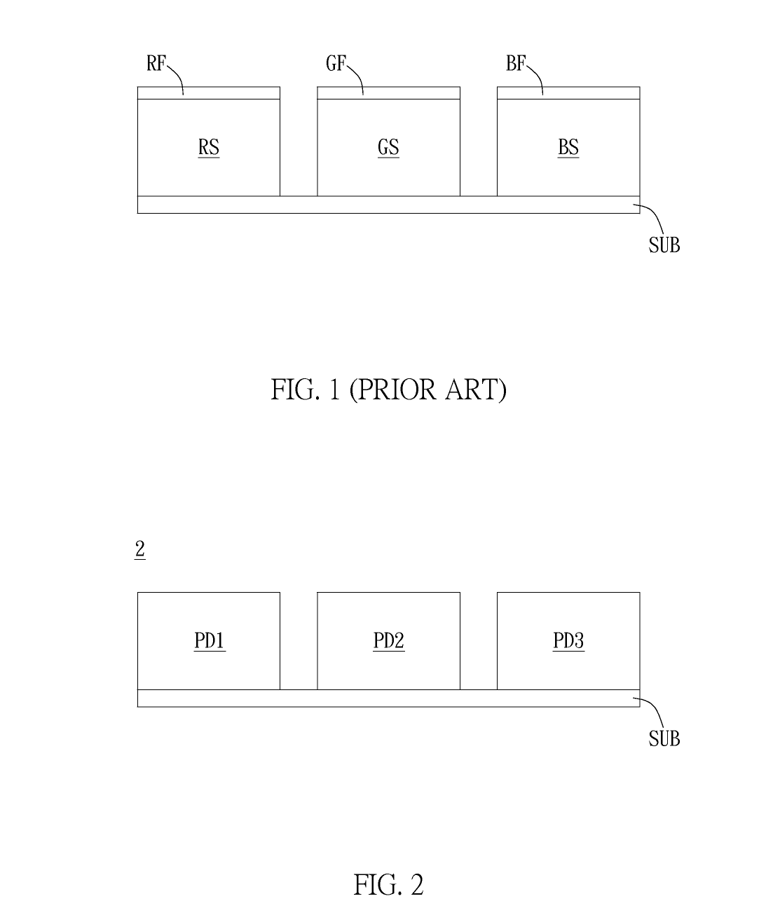

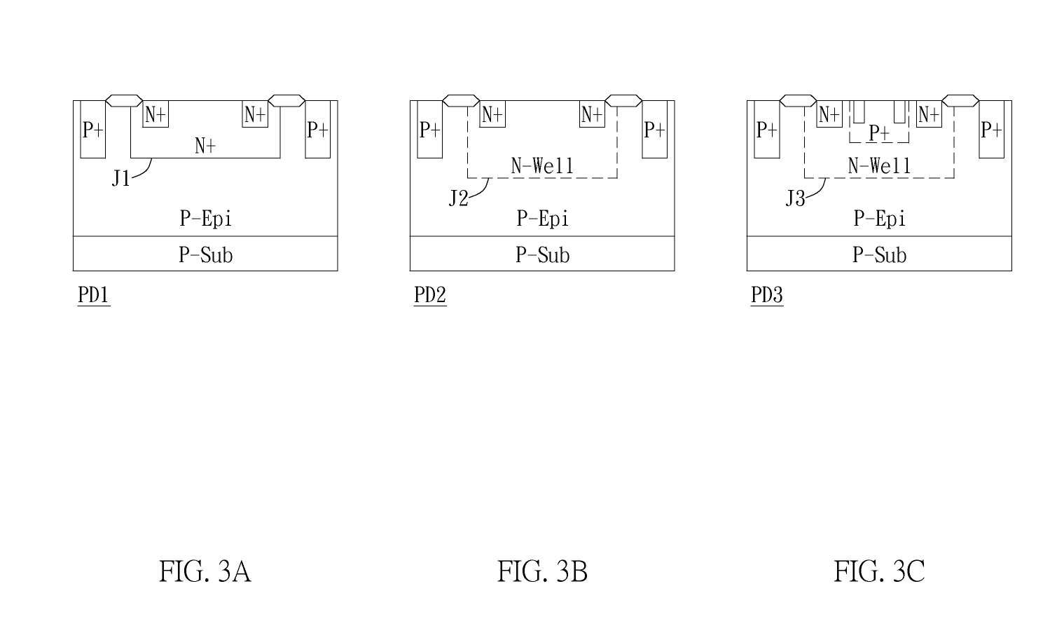

Please refer to FIG. 2. FIG. 2 illustrates a schematic diagram of a structure of the photo sensing chip. As shown in FIG. 2, the photo sensing chip 2 includes a silicon substrate SUB, a first photo sensor PD1, a second photo sensor PD2, and a third photo sensor PD3. In this embodiment, the first photo sensor PD1, the second photo sensor PD2, and the third photo sensor PD3 are formed on the silicon substrate SUB side by side. It should be noticed that different from that a first color filter RF, a second color filter GF, and a third color filter BF are coated on the red-light sensor RS, the green-light sensor GS, and the blue-light sensor BS of the conventional photo sensing chip respectively illustrated in FIG. 1, no color filter is necessary to be coated on the first photo sensor PD1, the second photo sensor PD2, and the third photo sensor PD3 of the photo sensing chip 2.

In this embodiment, these photo sensors PD1˜PD3 can be different kinds of photo diode, such as a P-N junction photo diode or a P-I-N junction photo diode. It should be noticed that in order to make the photo sensors PD1˜PD3 to receive different light bands of an incident light respectively, different process parameters can be used to perform different doping processes on the silicon substrate SUB of the photo sensors PD1˜PD3 respectively.

In fact, the different process parameters are related to the material and concentration of the dopants used in the above-mentioned different doping processes. For example, if the material of the dopant added into the silicon substrate is a trivalent element (e.g., boron), a P-type semiconductor region will be formed in the silicon substrate; if the material of the dopant added into the silicon substrate is a pentavalent element (e.g., phosphorus), an N-type semiconductor region will be formed in the silicon substrate.

By doing so, different types of P-N junction can be formed in the silicon substrate SUB of the photo sensors PD1˜PD3 respectively, and the depth of the depletion region of the P-N junction can be adjusted by different doping concentration. For example, if phosphorus is used as the dopant added into the silicon substrate, the depth of the depletion region of the P-N junction formed by a higher phosphorus doping concentration 3*10¹⁷ cm⁻³ is larger than that formed by a lower phosphorus doping concentration 5*10¹⁵ cm⁻³.

From above, it can be found that the P-N junctions of the photo sensors PD1˜PD3 can have depletion regions of different depths by adding dopants of different materials and concentrations into the silicon substrate SUB in this embodiment. Because the depletion regions of different depths correspond to different light bands of the incident light respectively, the photo sensors PD1˜PD3 can use their depletion regions of different depths to receive the different light bands of the incident light and generate photo currents respectively.

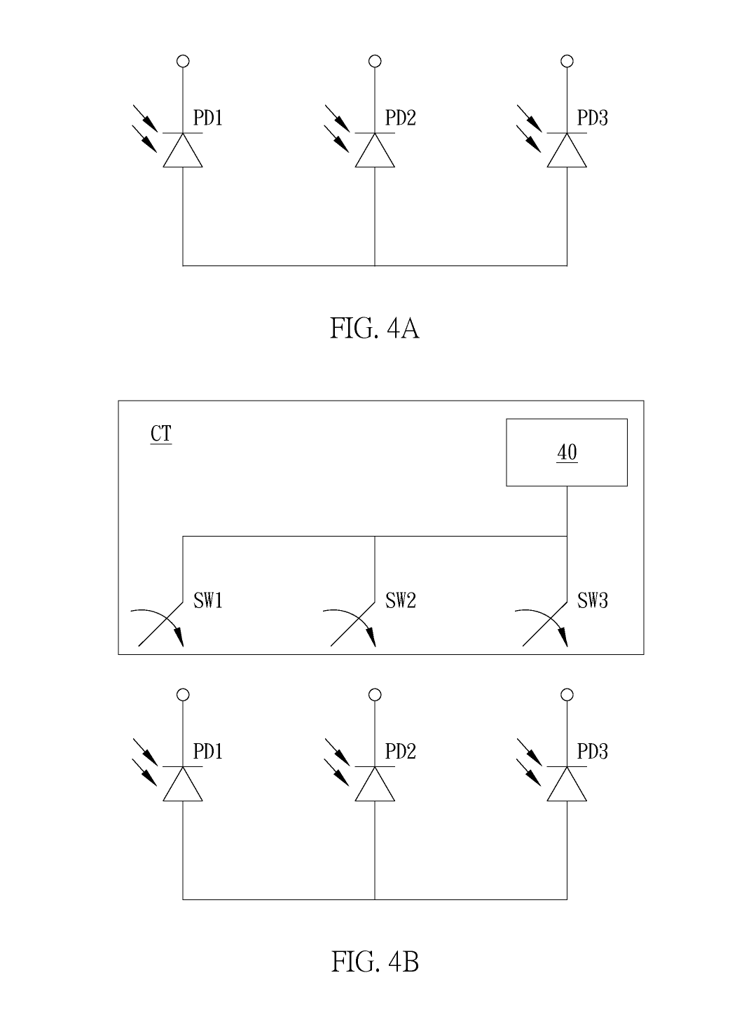

Then, the structures of the photo sensors PD1˜PD3 will be introduced respectively as follows. Please refer to FIG. 3A, FIG. 3B, and FIG. 3C. FIG. 3A, FIG. 3B, and FIG. 3C illustrate the cross-sectional diagrams of the first photo sensor PD1, the second photo sensor PD2, and the third photo sensor PD3 of FIG. 2 respectively.

As shown in FIG. 3A, the first photo sensor PD1 has a first P-N junction J1, and the first P-N junction J1 has a first depletion region. In this embodiment, the first P-N junction J1 is formed by the connection between a high-concentration N+ doping layer and a low-concentration P− epitaxial layer. When an incident light is emitted to the first photo sensor PD1, the first depletion region of the first P-N junction J1 will receive a corresponding first light band of the incident light and generate a first photo current.

As shown in FIG. 3B, the second photo sensor PD2 has a second P-N junction J2, and the second P-N junction J2 has a second depletion region. In this embodiment, the second P-N junction J2 is formed by the connection between a high-concentration N-well doping layer and a low-concentration P− epitaxial layer. When the incident light is emitted to the second photo sensor PD2, the second depletion region of the second P-N junction J2 will receive a corresponding second light band of the incident light and generate a second photo current.

As shown in FIG. 3C, the third photo sensor PD3 has a third P-N junction J3, and the third P-N junction J3 has a third depletion region. In this embodiment, the third P-N junction J3 is formed by the connection between a high-concentration N− well doping layer and a low-concentration P− epitaxial layer. Different from FIG. 3B, there is a higher concentration P+ doping layer in the N-well doping layer of FIG. 3C. When the incident light is emitted to the third photo sensor PD3, the third depletion region of the third P-N junction J3 will receive a corresponding third light band of the incident light and generate a third photo current.

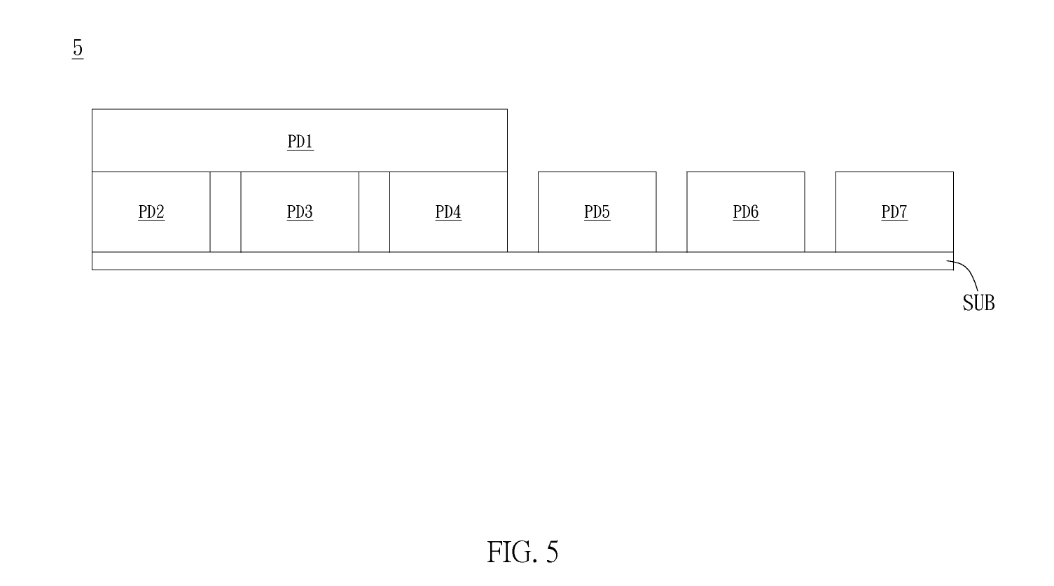

FIG. 4A illustrates the equivalent circuit diagram of the first photo sensor PD1, the second photo sensor PD2, and the third photo sensor PD3 of FIG. 2. FIG. 4B illustrates that the operation circuit CT operates the first photo current, the second photo current, and/or the third photo current generated by the first photo sensor PD1, the second photo sensor PD2, and the third photo sensor PD3. The operation circuit CT can selectively switch a first switch SW1, a second switch SW2, and a third switch SW3 on or off, so that the operation unit 40 can obtain an incident spectrum according to at least one of the first photo current of the first photo sensor PD1, the second photo current of the second photo sensor PD2, and the third photo current of the third photo sensor PD3.

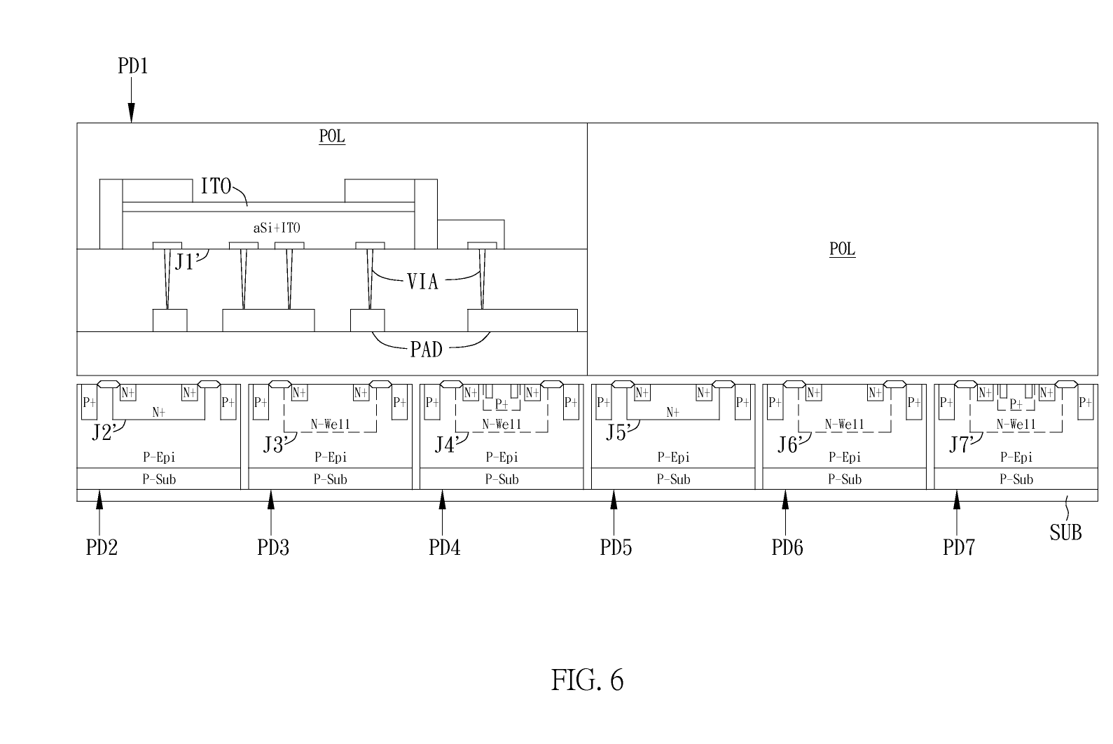

Please refer to FIG. 5. FIG. 5 illustrates a schematic diagram of another structure of the photo sensing chip. As shown in FIG. 5, the photo sensing chip 5 includes a silicon substrate SUB, a first photo sensor PD1, a second photo sensor PD2, a third photo sensor PD3, a fourth photo sensor PD4, a fifth photo sensor PD5, a sixth photo sensor PD6, and a seventh photo sensor PD7. In this embodiment, the second photo sensor PD2, the third photo sensor PD3, the fourth photo sensor PD4, the fifth photo sensor PD5, the sixth photo sensor PD6, and the seventh photo sensor PD7 are formed on the silicon substrate SUB side by side, and the first photo sensor PD1 is stacked above the second photo sensor PD2, the third photo sensor PD3, and the fourth photo sensor PD4.

It should be noticed that different from that the first color filter RF, the second color filter GF, and the third color filter BF are coated on the red-light sensor RS, the green-light sensor GS, and the blue-light sensor BS of the conventional photo sensing chip respectively illustrated in FIG. 1, no color filter is necessary to be coated on the first photo sensor PD1, the second photo sensor PD2, the third photo sensor PD3, the fourth photo sensor PD4, the fifth photo sensor PD5, the sixth photo sensor PD6, and the seventh photo sensor PD7 of the photo sensing chip 5 of the invention.

In this embodiment, the P-N junctions of the photo sensors PD1˜PD7 can have depletion regions of different depths by adding dopants of different materials and concentrations into the silicon substrate SUB. Because the depletion regions of different depths correspond to different light bands of the incident light respectively, the photo sensors PD1˜PD7 can use their depletion regions of different depths to receive the different light bands of the incident light and generate photo currents respectively.

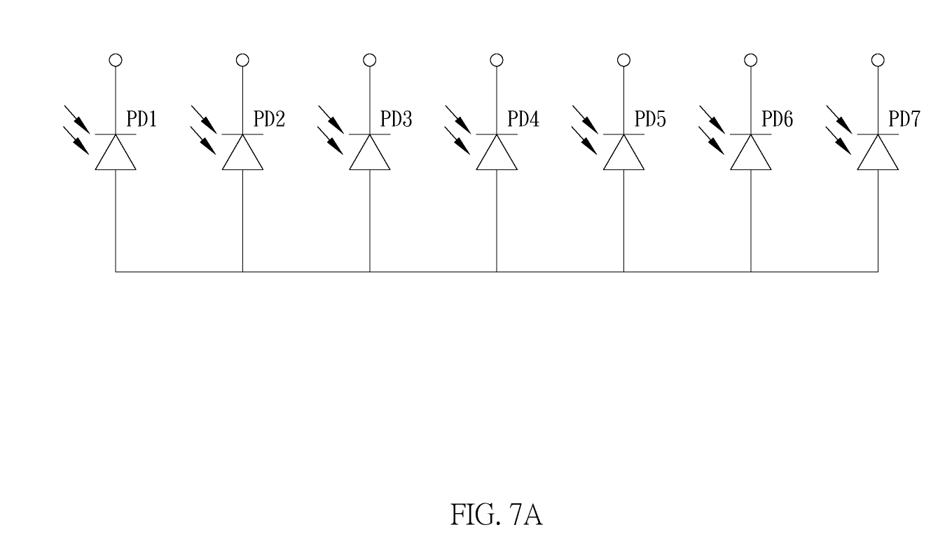

As shown in FIG. 6, the second photo sensor PD2, the third photo sensor PD3, the fourth photo sensor PD4, the fifth photo sensor PD5, the sixth photo sensor PD6, and the seventh photo sensor PD7 can be P-N junction photo diodes, and the first photo sensor PD1 can be a P-I-N junction photo diode. It should be noticed that the first photo sensor PD1 stacked above the second photo sensor PD2˜the fourth photo sensor PD4 on the photo sensing chip 5 would be helpful to reduce the photo sensing area of the photo sensing chip 5.

The first photo sensor PD1 has a P-I-N junction J1′ and the P-I-N junction J1′ has a first depletion region. When an incident light is emitted to the first photo sensor PD1, the first depletion region of the P-I-N junction J1′ will receive a corresponding first light band of the incident light and generate a first photo current.

The second photo sensor PD2 has a second P-N junction J2, and the second P-N junction J2 has a second depletion region. When the incident light is emitted to the second photo sensor PD2, the second depletion region of the second P-N junction J2 will receive a corresponding second light band of the incident light and generate a second photo current.

The third photo sensor PD3 has a third P-N junction J3, and the third P-N junction J3 has a third depletion region. When the incident light is emitted to the third photo sensor PD3, the third depletion region of the third P-N junction J3 will receive a corresponding third light band of the incident light and generate a third photo current.

The fourth photo sensor PD4 has a fourth P-N junction J4, and the fourth P-N junction J4 has a fourth depletion region. When the incident light is emitted to the fourth photo sensor PD4, the fourth depletion region of the fourth P-N junction J4 will receive a corresponding fourth light band of the incident light and generate a fourth photo current.

No other photo sensor is stacked above the fifth photo sensor PD5, the sixth photo sensor PD6, and the seventh photo sensor PD7. The fifth photo sensor PD5 has a fifth P-N junction J5, and the fifth P-N junction J5 has a fifth depletion region. When the incident light is emitted to the fifth photo sensor PD5, the fifth depletion region of the fifth P-N junction J5 will receive a corresponding fifth light band of the incident light and generate a fifth photo current.

The sixth photo sensor PD6 has a sixth P-N junction J6, and the sixth P-N junction J6 has a sixth depletion region. When the incident light is emitted to the sixth photo sensor PD6, the sixth depletion region of the sixth P-N junction J6 will receive a corresponding sixth light band of the incident light and generate a sixth photo current.

The seventh photo sensor PD7 has a seventh P-N junction J7, and the seventh P-N junction J7 has a seventh depletion region. When the incident light is emitted to the seventh photo sensor PD7, the seventh depletion region of the seventh P-N junction J7 will receive a corresponding seventh light band of the incident light and generate a seventh photo current.

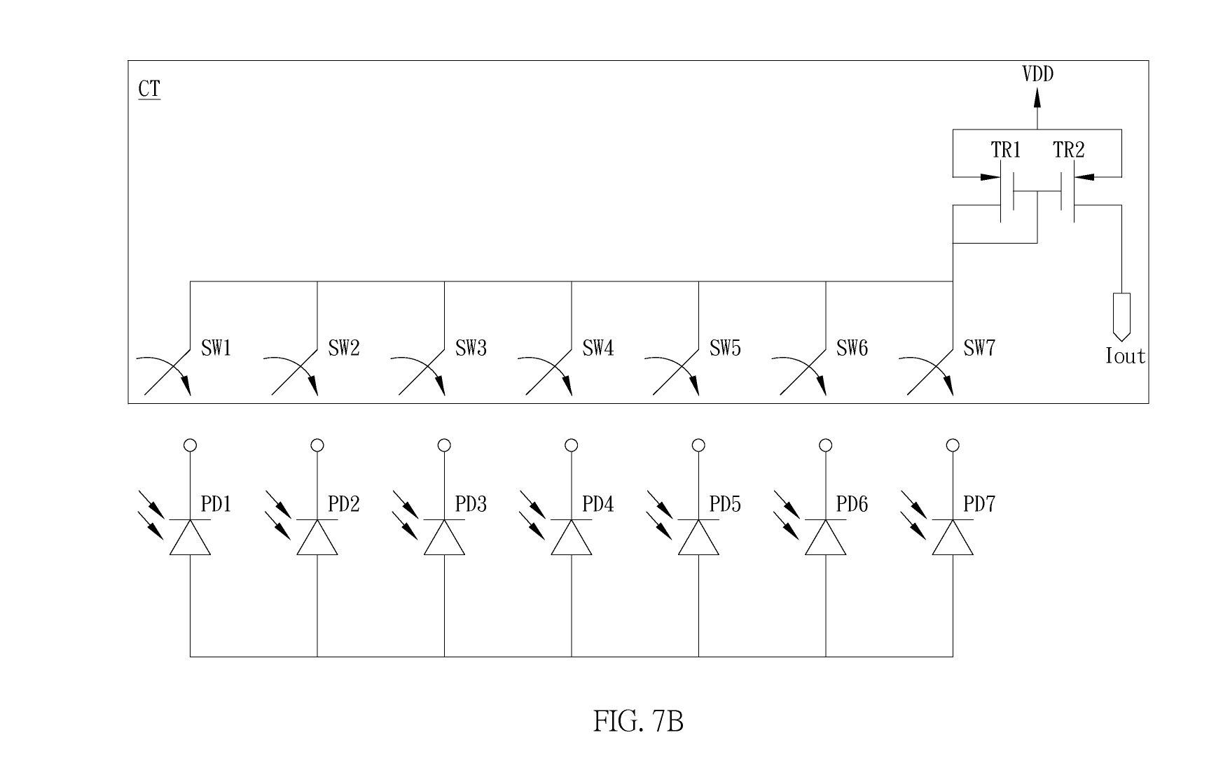

FIG. 7A illustrates the equivalent circuit diagram of the first photo sensor PD1, the second photo sensor PD2, the third photo sensor PD3, the fourth photo sensor PD4, the fifth photo sensor PD5, the sixth photo sensor PD6, and the seventh photo sensor PD7 of FIG. 5. FIG. 7B illustrates that the operation circuit CT operates the first photo current, the second photo current, the third photo current, the fourth photo current, the fifth photo current, the sixth photo current, and/or the seventh photo current generated by the first photo sensor PD1, the second photo sensor PD2, the third photo sensor PD3, the fourth photo sensor PD4, the fifth photo sensor PD5, the sixth photo sensor PD6, and the seventh photo sensor PD7. The operation circuit CT can selectively switch on or off a first switch SW1, a second switch SW2, a third switch SW3, a fourth switch SW4, a fifth switch SW5, a sixth switch SW6, and/or a seventh switch SW7 to obtain an incident spectrum according to at least one of the first photo current of the first photo sensor PD1, the second photo current of the second photo sensor PD2, the third photo current of the third photo sensor PD3, the fourth photo current of the fourth photo sensor PD4, the fifth photo current of the fifth photo sensor PD5, the sixth photo current of the sixth photo sensor PD6, and the seventh photo current of the seventh photo sensor PD7.

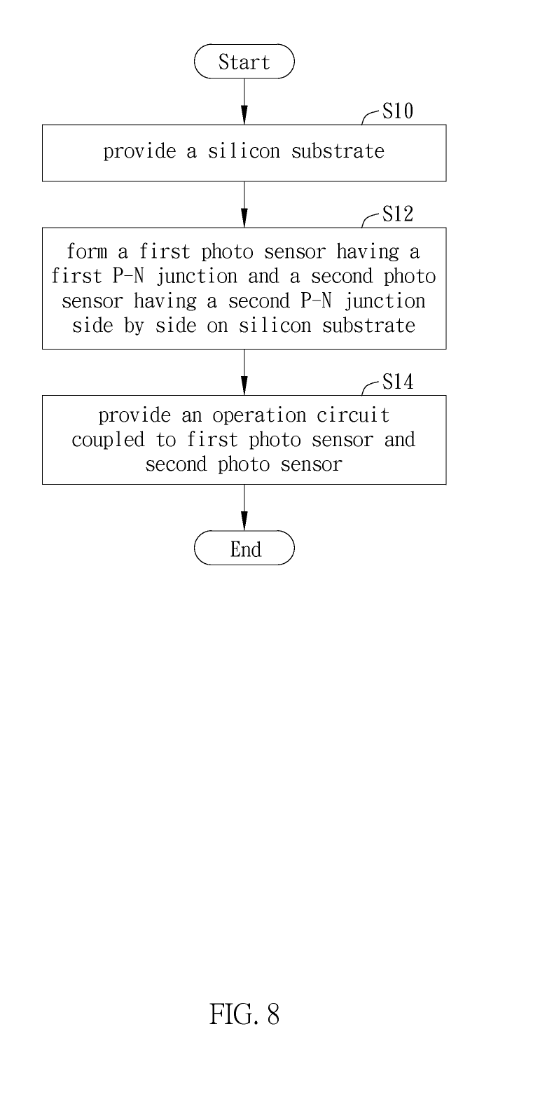

Another preferred embodiment of the invention is a photo sensing chip manufacturing method. In practical applications, the photo sensing chip manufacturing method is used to manufacture a photo sensing chip having photo sensors. Please refer to FIG. 8. FIG. 8 illustrates a flow chart of the photo sensing chip manufacturing method in this embodiment.

As shown in FIG. 8, in the step S10, the method provides a silicon substrate. In the step S12, the method forms a first photo sensor having a first P-N junction and a second photo sensor having a second P-N junction side by side on the silicon substrate. Wherein, the first P-N junction of the first photo sensor has a first depletion region, and the first depletion region receives a first light band of an incident light and generates a first photo current; the second P-N junction of the second photo sensor has a second depletion region, and the second depletion region receives a second light band of the incident light and generates a second photo current. In the step S14, the method provides an operation circuit coupled to the first photo sensor and the second photo sensor. The operation circuit is used to obtain an incident spectrum according to at least one of the first photo current and the second photo current.

It should be noticed that a first process parameter corresponds to the first depletion region and a second process parameter corresponds to the second depletion region; wherein, the first process parameter is different from the second process parameter. In fact, the first process parameter and the second process parameter are related to the doping material and also related to the depths of the first depletion region and the second depletion region. In this embodiment, the first doping material of the first depletion region and the second doping material of the second depletion region are different, and the first depth of the first depletion region and the second depth of the second depletion region are also different.

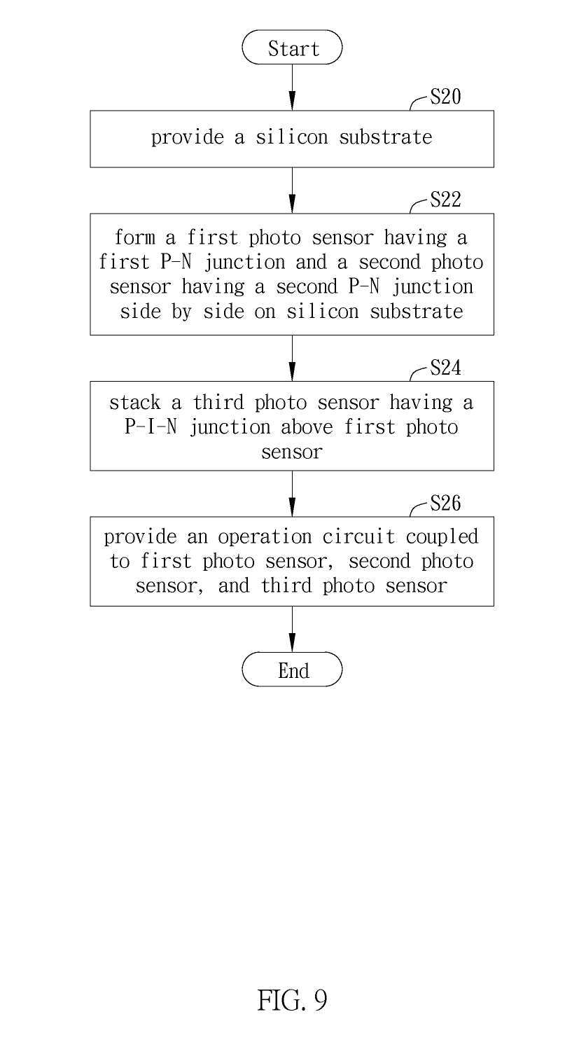

Please refer to FIG. 9. FIG. 9 illustrates a flow chart of the photo sensing chip manufacturing method in another embodiment. As shown in FIG. 9, in the step S20, the method provides a silicon substrate. In the step S22, the method forms a first photo sensor having a first P-N junction and a second photo sensor having a second P-N junction side by side on the silicon substrate. In the step S24, the method stacks a third photo sensor having a P-I-N junction above the first photo sensor.

Wherein, the P-I-N junction of the third photo sensor has a third depletion region, and the third depletion region receives a third light band of the incident light and generates a third photo current. The first P-N junction of the first photo sensor has a first depletion region, and the first depletion region receives a first light band of an incident light passing through the third photo sensor and then entering the first photo sensor and generates a first photo current; the second P-N junction of the second photo sensor has a second depletion region, and the second depletion region receives a second light band of the incident light and generates a second photo current. In the step S26, the method provides an operation circuit coupled to the first photo sensor, the second photo sensor, and the third photo sensor. The operation circuit is used to obtain an incident spectrum according to at least one of the first photo current, the second photo current, and the third photo current.

Compared with the prior arts, since it is unnecessary to form any color filter in the photo sensing chip having photo sensors of the invention, the photo sensing chip of the invention can be made in the same plant to effectively lower the manufacturing and transportation costs and reduce the process complexity. In addition, the photo sensors can be stacked on the photo sensing chip in the invention to reduce the photo sensing area of the photo sensing chip to achieve effects of reducing area, lowering cost, and enhancing chip efficiency.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A photo sensing chip, comprising:
a silicon substrate; and
a plurality of photo sensors formed on the silicon substrate, the photo sensors comprising:
a first photo sensor having a first P-N junction, wherein a first depletion region is formed at the first P-N junction for receiving a first light band of an incident light and generating a first photo current; and
a second photo sensor having a second P-N junction, wherein a second depletion region is formed at the second P-N junction for receiving a second light band of the incident light and generating a second photo current;
wherein a first process parameter corresponds to the first depletion region and a second process parameter corresponds to the second depletion region, the first process parameter and the second process parameter are different.

2. The photo sensing chip of claim 1, wherein the first process parameter and the second process parameter are related to a doping material, a first doping material of the first depletion region and a second doping material of the second depletion region are different.

3. The photo sensing chip of claim 1, wherein the first process parameter and the second process parameter are related to depths of the first depletion region and the second depletion region, a first depth of the first depletion region and a second depth of the second depletion region are different.

4. The photo sensing chip of claim 1, wherein the first photo sensor and the second photo sensor are formed on the silicon substrate side by side or stacked on the silicon substrate.

5. The photo sensing chip of claim 1, further comprising:
an operation circuit, coupled to the photo sensors, for obtaining an incident spectrum according to at least one of the first photo current and the second photo current.

6. The photo sensing chip of claim 1, wherein the photo sensors are selected from a group formed by a red-light sensor, a green-light sensor, a blue-light sensor, an ambient light sensor, a proximity sensor, and a UV sensor.

7. A method of manufacturing a photo sensing chip, comprising steps of:
(a) providing a silicon substrate; and
(b) forming a plurality of photo sensors on the silicon substrate;
the step (b) comprising steps of:
(b1) forming a first photo sensor having a first P-N junction, and forming a first depletion region at the first P-N junction to receive a first light band of an incident light and generate a first photo current; and
(b2) forming a second photo sensor having a second P-N junction, and forming a second depletion region at the second P-N junction to receive a second light band of the incident light and generate a second photo current,
wherein a first process parameter corresponds to the first depletion region and a second process parameter corresponds to the second depletion region, the first process parameter and the second process parameter are different.

8. The method of claim 7, wherein the first process parameter and the second process parameter are related to a doping material, a first doping material of the first depletion region and a second doping material of the second depletion region are different.

9. The method of claim 7, wherein the first process parameter and the second process parameter are related to depths of the first depletion region and the second depletion region, a first depth of the first depletion region and a second depth of the second depletion region are different.

10. The method of claim 7, wherein the first photo sensor formed in the step (b1) and the second photo sensor formed in the step (b2) are formed on the silicon substrate side by side or stacked on the silicon substrate.

11. The method of claim 7, further comprising a step of:
(c) providing an operation circuit coupled to the photo sensors to obtain an incident spectrum according to at least one of the first photo current and the second photo current.

12. The method of claim 7, wherein the photo sensors are selected from a group formed by a red-light sensor, a green-light sensor, a blue-light sensor, an ambient light sensor, a proximity sensor, and a UV sensor.
